(19) United States
(12) Patent Application Publication
(10) Pub. No.: US 2014/0355327 A1
(43) Pub. Date: Dec. 4, 2014

(54) MEMORY MODULE AND MEMORY SYSTEM HAVING THE SAME

(71) Applicant: SAMSUNG ELECTRONICS CO., LTD., Suwon-si (KR)

(72) Inventors: Hyun Il BYUN, Seongnam-si (KR); Gopal RAGHAVAN, Thousand Oaks, CA (US); In Sung JOE, Seoul (KR)

(73) Assignee: SAMSUNG ELECTRONICS CO., LTD., Suwon-si (KR)

(21) Appl. No.: 14/284,787

(22) Filed: May 22, 2014

(30) Foreign Application Priority Data
Jun. 4, 2013 (KR) 10-2013-0064274

(51) Int. Cl. G11C 5/06

(52) U.S. Cl. CPC G11C 5/063
USPC 365/64

(57) ABSTRACT

A memory system includes a controller, a first memory module, and a second memory module. The first memory module includes a first number of memory packages and a second number of memory packages. The second memory module includes a third number of memory packages and a fourth number of memory packages. The first and third numbers of memory packages are selected to correspond to a same rank based on control signals from the controller. The control signals are transmitted from the controller to the first and second memory modules through respective ones of a plurality of optical channels.

### CROSS-REFERENCE TO RELATED APPLICATION

Korean Patent Application No. 10-2013-0064274, filed on Jun. 4, 2013, and entitled, “Memory Module and Memory System Having The Same,” is incorporated by reference herein in its entirety.

### BACKGROUND

1. Field

One or more embodiments described herein relate to processing or storing data.

2. Description of the Related Art

A memory system transmits electrical signals between a memory controller and a memory module. However, a signal integrity problem may occur during transmission of these signals. In an attempt to order to solve the problem, memory systems which use one or more optical channels have been proposed. However, these systems consume excessive amounts of power as a result of light-source switching and other losses.

### SUMMARY

In accordance with one embodiments, a memory module includes a printed circuit board (PCB); a plurality of memory packages on the PCB; an optical-electrical converter on the PCB; and a select circuit on the PCB to select at least one of the memory packages, wherein the at least one memory package is to process electrical signals output from the optical-electrical converter.

The select circuit may include a switch circuit to transmit the electrical signals to the at least one memory package in response to a switch signal from a memory controller. The select circuit may enable the at least one memory package only in response to a control signal from a memory controller.

The memory module may include a light source on the PCB, wherein the optical-electrical converter may convert input optical signals to the electrical signals in response to an optical signal from the light source. The optical-electrical converter and the light source may be included in one package. The light source may be included in a first chip, the optical-electrical converter may be included in a second chip, and the first chip may be bonded to the second chip based on a flip-chip configuration. The optical-electrical converter may deserialize a serialized input optical signal to generate the electrical signals.

In accordance with another embodiment, a memory system includes a plurality of memory modules and a memory controller to control the memory modules, wherein each of the memory modules includes a printed circuit board (PCB); a plurality of memory packages on the PCB; an optical-electrical converter on the PCB; and a select circuit on the PCB to select at least one of the memory packages, wherein the at least one memory package is to process electrical signals output from the optical-electrical converter.

The memory system may include a plurality of light sources allocated to respective ones of the memory modules, wherein the optical-electrical converter of each of the memory modules may convert input optical signals to the electrical signals in response to an optical signal output from a respective one of the light sources. The light sources may be mounted on respective ones of the memory modules.

The optical-electrical converter of respective ones of the memory modules and a respective one of the light sources may be included in one package.

The memory system may include a plurality of optical channels connected between the memory controller and the optical-electrical converter of respective ones of the memory modules.

The select circuit may include a switch circuit to transmit the electrical signals to at least one of the memory packages in response to a switch signal from the memory controller. The select circuit may enable the at least one memory package only in response to a control signal from the memory controller.

The memory controller may include a light source and an electrical-optical converter to convert electrical signals to be transmitted to the memory modules into optical signals in response to an optical signal output from the light source, wherein the light source and electrical-optical converter may be included in one package.

In accordance with one embodiment, a memory system includes a controller, a first memory module including a first number of memory packages and a second number of memory packages, and a second memory module including a third number of memory packages and a fourth number of memory packages, wherein the first and third numbers of memory packages are selected to correspond to a same rank based on control signals from the controller and wherein the control signals are transmitted from the controller to the first and second memory modules through respective ones of a plurality of optical channels.

The memory system may include a first selector to select the first number of memory packages, and a second selector to select the third number of memory packages. The memory system may include a first optical-to-electrical (O/E) converter between the controller and the first selector and a second O/E converter between the controller and the second selector, wherein the first O/E converter may convert the control signal through a first one of the optical channels based on a first light signal and wherein the second O/E converter may convert the control signal through a second one of the optical channels based on a second light signal.

The first and second light signals may have different optical wavelengths. The second number of memory packages may be in a column different from the second number of memory packages, and the fourth number of memory packages may be in a column different from the third number of memory packages.

### BRIEF DESCRIPTION OF THE DRAWINGS

Features will become apparent to those of skill in the art by describing in detail exemplary embodiments with reference to the attached drawings in which:

FIGS. 1 to 4 illustrate one embodiment of a memory system;

FIGS. 5 to 7 illustrate other embodiments of memory systems;

FIG. 8 illustrates an optical connection between a memory controller and memory modules;

FIGS. 9 to 10 illustrate other embodiments of memory systems;

FIGS. 11 to 12 illustrate other embodiments of memory systems; and

FIG. 13 illustrates a memory system including a plurality of memory modules.

### DETAILED DESCRIPTION

Example embodiments are described more fully hereinafter with reference to the accompanying drawings; however, they may be embodied in different forms and should not be construed as limited to the embodiments set forth herein. Rather, these embodiments are provided so that this disclosure will be thorough and complete, and will fully convey exemplary implementations to those skilled in the art.

In the drawing figures, the dimensions of layers and regions may be exaggerated for clarity of illustration. It will also be understood that when a layer or element is referred to as being “on” another layer or substrate, it can be directly on the other layer or substrate, or intervening layers may also be present. Further, it will be understood that when a layer is referred to as being “under” another layer, it can be directly under, and one or more intervening layers may also be present. In addition, it will also be understood that when a layer is referred to as being “between” two layers, it can be the only layer between the two layers, or one or more intervening layers may also be present. Like reference numerals refer to like elements throughout.

Herein, an electrical signal be understood to include a serial electrical signal or a parallel electrical signal, which may include serial data or parallel data, control information, and/or other types of information.

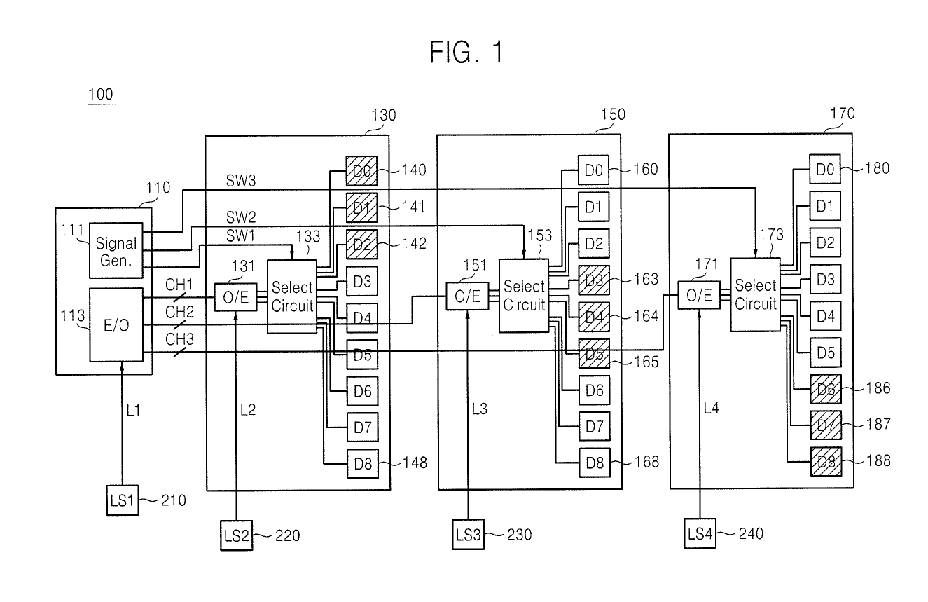

FIGS. 1 to 4 illustrate embodiments of memory systems using a switch. Referring to FIG. 1, a memory system 100 includes a memory controller 110, a plurality of memory modules 130, 150, and 170, and a plurality of light sources 210, 220, 230, and 240. The memory system 100 may be included in a personal computer, laptop computer, server, data server, web server, or another type of electronic system or device. For illustrative purposes, memory system 100 is shown to include three memory modules 130, 150, and 170 which include nine memory packages 140 to 148, 160 to 168, and 180 to 188, respectively.

Each of the memory packages 140 to 148, 160 to 168, and 180 to 188 may include one or more memory chips. Each memory chip may be a volatile memory chip or a non-volatile memory chip. Two or more memory chips in each of the memory packages 140 to 148, 160 to 168, and 180 to 188 may be connected, for example, through bonding wires or through silicon vias (TSVs).

The memory controller 110 may control operation of the memory modules 130, 150, and 170. The memory controller 110 includes a select (or switch) signal generator 111 and an electrical-optical converter 113. The select (or switch) signal generator 111 may generate each select (or switch) signal SW1, SW2, and SW3 for controlling respective ones of select circuits 133, 153, and 173 in the memory modules 130, 150, and 170.

The electrical-optical converter 113 may convert electrical signal(s) into optical signal(s) using an optical signal L1 output from the first light source 210. The electro-optical converter 113 may transmit the converted optical signal(s) to the plurality of memory modules 130, 150, and 170 through respective channels CH1, CH2, and CH3. In one embodiment, a bus width (or bandwidth) of each of the plurality of channels CH1, CH2, and CH3 may be the same as each other. However, in other embodiments the bus widths (or bandwidths) of these channels may be different.

The electrical-optical converter 113 may transmit optical signals to the memory modules 130, 150, and 170 through the channels CH1, CH2, and CH3. The optical signals may include, for example, data signals, control signals, and/or types of signals. For illustrative purposes, components for a write operation are shown.

The electrical-optical converter 113 may include an optical serializer. The optical serializer may serialize parallel electrical signals into a serial optical signal using an optical signal L1. Each of the channels CH1, CH2, and CH3 may have a configuration for transmitting the serialized optical signal.

The plurality of memory modules 130, 150, and 170 may receive optical signals or the serialized optical signal output from the memory controller 110 through respective ones of the channels CH1, CH2, and CH3. For example, each of the plurality of memory modules 130, 150, and 170 may be an optical dual in-line memory module (DIMM), an optical fully buffered DIMM (FB-DIMM), an optical small outline DIMM (SO-DIMM), an optical registered DIMM (RDIMM), an optical Load Reduced DIMM (LRDIMM), Unbuffered DIMM (UDIMM), an optical MicroDIMM, or an optical single in-line memory module (SIMM).

The first memory module 130 includes a first optical-electrical converter 131, a first select circuit 133, and the plurality of memory packages 140 to 148. For example, the first memory module 130 includes the first optical-electrical converter 131, the first select circuit 133, and the plurality of memory packages 140 to 148, which are mounted on a printed circuit board (PCB).

The first optical-electrical converter 131 may receive an optical signal output from the electrical-optical converter 113 of the memory controller 110 through a first optical channel CH1. The first optical-electrical converter 131 may convert the received optical signal into an electrical signal using an optical signal L2. The first optical-electrical converter 131 may include an optical deserializer. The optical deserializer may deserialize the serialized optical signal into the parallel electrical signals using the optical signal L2.

The first select circuit 133 may control signal transmission paths between the first optical-electrical converter 131 and the plurality of memory packages 140 to 148 in response to a first select signal SW1 output from the memory controller 110. Some of the memory packages 140, 141, and 142 among the plurality of memory packages 140 to 148 may process an electrical signal output from the first optical-electrical converter 131.

A second memory module 150 includes a second optical-electrical converter 151, a second select circuit 153, and the plurality of memory packages 160 to 168. For example, the second memory module 150 may include the second optical-electrical converter 151, the second select circuit 153, and the plurality of memory packages 160 to 168 which are mounted on the PCB.

The second optical-electrical converter 151 may receive an optical signal output from the electrical-optical converter 113 of the memory controller 110 through a second optical channel CH2. The second optical-electrical converter 151 may convert the received optical signal into an electrical signal using an optical signal L3.

The second select circuit 153 may control signal transmission paths between the second optical-electrical converter 151 and the plurality of memory packages 160 to 168 in response to a second select signal SW2 output from the memory controller 110. Some of the memory packages 163, 164, and 165 among the plurality of memory packages 160 to 168 may process an electrical signal output from the optical-electrical converter 151.

A third memory module 170 includes a third optical-electrical converter 171, a third select circuit 173, and the plurality of memory packages 180 to 188. For example, the third memory module 170 includes the third optical-electrical converter 171, the third select circuit 173, and the plurality of memory packages 180 to 188, which are mounted on the PCB.

The third optical-electrical converter 171 may receive an optical signal output from the electrical-optical converter 113 of the memory controller 110 through a third optical channel CH3. The third optical-electrical converter 171 may convert the received optical signal into an electrical signal using an optical signal L4. A wavelength and/or power of the optical signals L1, L2, L3, and L4 may be equal or different from one another.

The third select circuit 173 may control signal transmission paths between the third optical-electrical converter 171 and the plurality of memory packages 180 to 188 in response to a third select signal SW3 output from the memory controller 110. Some of the memory packages 186, 187, and 188 among the plurality of memory packages 180 to 188 may process an electrical signal output from optical-electrical converter 171.

Light source 210, 220, 230, and 240 may be included outside or inside components 110, 130, 150, and 170. For illustrative purposes, light sources 220, 230, and 240 are shown in FIG. 1 as being outside memory module 130, 150, and 170.

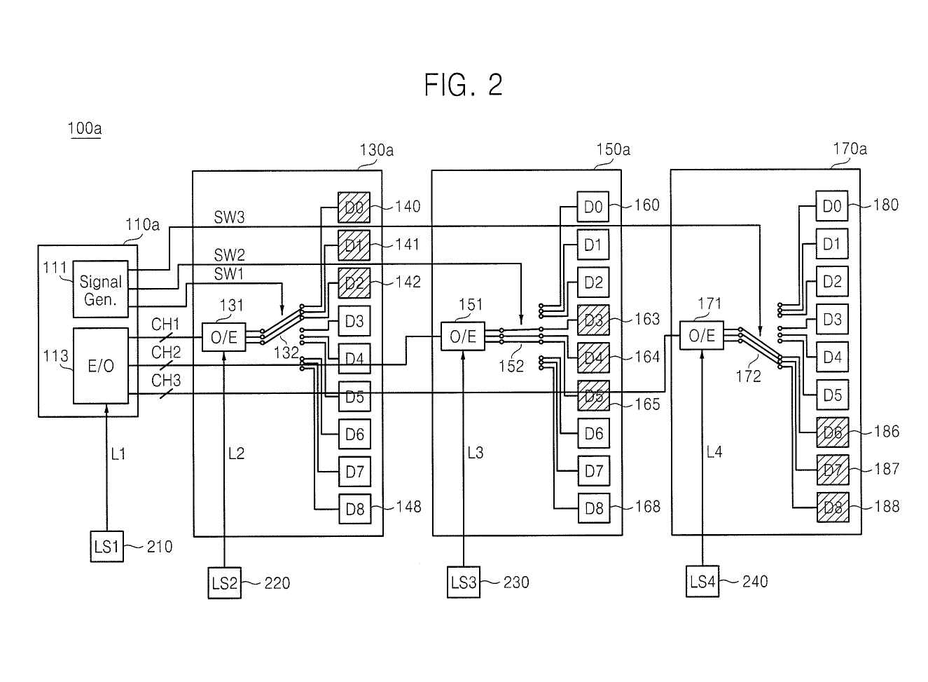

The memory packages of the memory modules may be arranged in one or more ranks. For example, as illustrated in FIG. 2, three memory packages 140, 141, and 142 in a first memory module 130a, three memory packages 163, 164, and 165 in a second memory module 150a, and three memory packages 186, 187, and 188 in a third memory module 170a may correspond to a first rank.

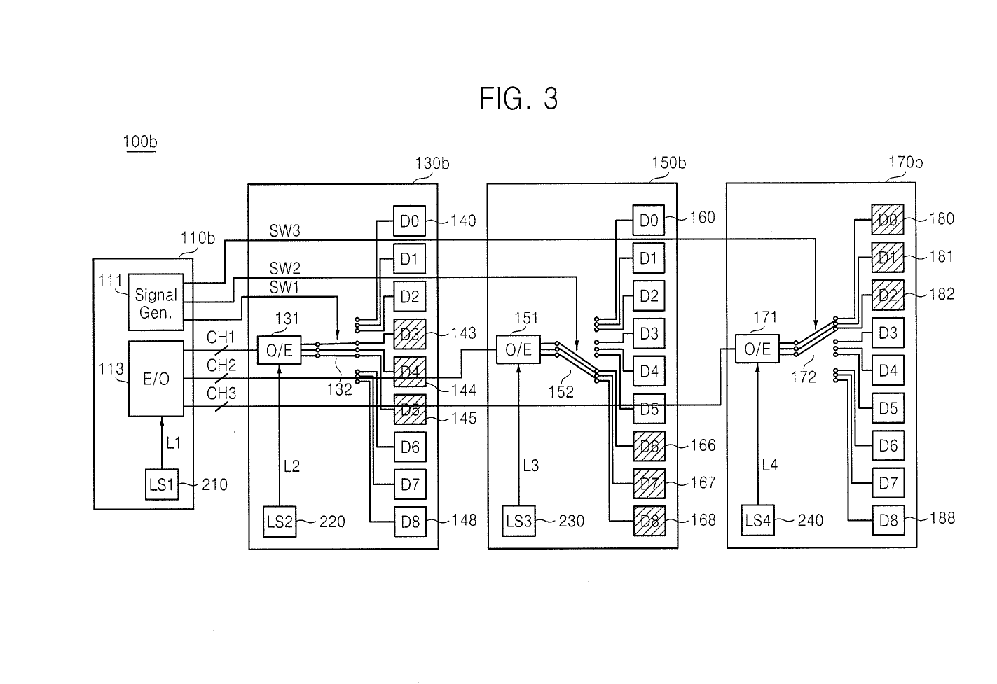

As illustrated in FIG. 3, three memory packages 143, 144, and 145 in a first memory module 130b, three memory packages 166, 167, and 168 in a second memory module 150b, and three memory packages 180, 181, and 182 in a third memory module 170b may correspond to a second rank.

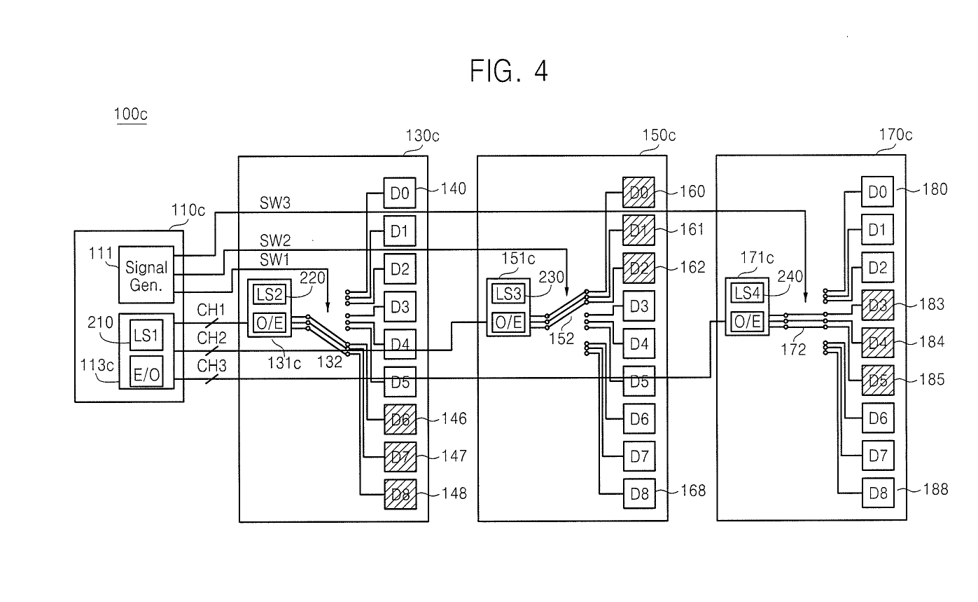

As illustrated in FIG. 4. three memory packages 146, 147, and 148 in a first memory module 130c, three memory packages 160, 161, and 162 in a second memory module 150c, and three memory packages 183, 184, and 185 in a third memory module 170c may compose a third rank.

The light sources 210, 220, 230, and 240 generate optical signals L1, L2, L3, and L4 for optical converters 113, 131, 151, and 171. The light sources 210, 220, 230, and 240 may be a laser diode (LD) or a light emitting diode (LED). For example, the first light source 210 may generate optical signal L1 for electrical-optical conversion (e.g., for converting an electrical signal into an optical signal) to be performed electrical-optical converter 113 of the memory controller 110.

The second light source 220 may generate the optical signal L2 for optical-electrical conversion (e.g., for converting an optical signal into an electrical signal) to be performed by the first optical-electrical converter 131 of first memory module 130.

The third light source 230 may generate an optical signal L3 for optical-electrical conversion to be performed by the second optical-electrical converter 151 of the second memory module 150.

The fourth light source 240 may generate the optical signal L3 for optical-electrical conversion to be performed by the third optical-electrical converter 171 of the third memory module 170.

Referring to FIGS. 1 and 2, a memory system 100a includes a memory controller 110a, a plurality of memory modules 130a, 150a, and 170a, and the plurality of light sources 210, 220, 230, and 240. The structure and operation of the memory controller 110a of FIG. 2 may be substantially the same as memory controller 110 of FIG. 1.

The first memory module 130a includes a first optical-electrical converter 131, a first switch 132, and the plurality of memory packages 140 to 148. The first select circuit 133 of FIG. 1 is replaced with a first switch 132 in FIG. 2. Otherwise, the first memory module 130a of FIG. 2 may be substantially the same as the first memory module 130 of FIG. 1 in structure.

The first switch 132 transmits electrical signals from the first optical-electrical converter 131 to three memory packages 140, 141, and 142 in response to a first select signal SW1, i.e., a first switch signal. The first switch 132 is an example embodiment of the first select circuit 133.

The second memory module 150a includes the first optical-electrical converter 151, a second switch 152, and the plurality of memory packages 160 to 168. The second select circuit 153 of FIG. 1 is replaced with the second switch 152 of FIG. 2. Otherwise, the second memory module 150a of FIG. 2 may be substantially the same as the second memory module 150 of FIG. 1 in structure.

The second switch 152 transmits electrical signals from the second optical-electrical converter 151 to three memory packages 163, 164, and 165 in response to a second select signal SW2, i.e., a second switch signal. The second switch 152 is an example embodiment of the second select circuit 153.

The third memory module 170a includes the third optical-electrical converter 171, the third switch 172, and the plurality of memory packages 180 to 188. The third select circuit 173 of FIG. 1 is replaced with a third switch 172 of FIG. 2. Otherwise, the third memory module 170a of FIG. 2 and the third memory module 170 of FIG. 1 may be substantially the same in a structure.

The third switch 172 transmits electrical signals from the third optical-electrical converter 171 to three memory packages 186, 187, and 188 in response to a third select signal SW3, i.e., a third switch signal. The third switch 172 is an example embodiment of the third select circuit 173.

As described referring to FIGS. 1 and 2, three memory packages 140, 141, and 142 in the first memory module 130 or 130a, three memory packages 163, 164, and 165 in the second memory module 150 or 150a, and three memory packages 186, 187, and 188 in the third memory module 170 or 170a may correspond to one rank.

Three memory packages may be selected among nine memory packages 140 to 148 according to a composition of first switch 132. Three memory packages 163, 164, and 165 may be selected among nine memory packages 160 to 168 according to a composition of second switch 152. Three memory packages may be selected among nine memory packages 180 to 188 according to a composition of the third switch 12.

Accordingly, three memory packages selected in the first memory module 130a, three memory packages selected in the second memory module 150a, and three memory packages selected in the third memory module 170a may correspond to another rank. The number of memory packages in memory module 130a, 150a, and 170a may be the same or different for each of the ranks.

Referring to FIGS. 1 and 3, memory system 100b includes a memory controller 110b and a plurality of memory modules 130b, 150b, and 170b. The memory controller 110b includes a switch signal generator 111, an electrical-optical converter 113, and a first light source 210. That is, unlike the memory controller 110a in FIG. 1, the memory controller 110b of FIG. 2 includes the first light source 210.

The first memory module 130b includes the first optical-electrical converter 131, the first switch 132, the plurality of memory packages 140 to 148, and the second light source 220, which are mounted on the PCB. The first switch 132 transmits an electrical signal output from the first optical-electrical converter 131 to three memory packages 143, 144, and 145 in response to a first select signal SW1, i.e., a first switch signal.

The second memory module 150b includes the second optical-electrical converter 151, the second switch 152, the plurality of memory packages 160 to 168, and the third light source 230, which are mounted on the PCB. The second switch 152 transmits an electrical signal output from the second optical-electrical converter 151 to three memory packages 166, 167, and 168 in response to a second select signal SW2, i.e., a second switch signal. The third memory module 170b includes the third optical-electrical converter 171, the third switch 172, the plurality of memory packages 180 to 188, and a fourth light source 240, which are mounted on the PCB.

The third switch 172 transmits an electrical signal output from the third optical-electrical converter 171 to three memory packages 180, 181, and 182 in response to the third select signal SW2, i.e., a third switch signal.

Three memory packages may be selected among nine memory packages 140 to 148 according to the composition the first switch 132, three memory packages may be selected among nine memory packages 160 to 168 according to the composition the second switch 152, and three memory packages may be selected among nine memory packages 180 to 188 according to the composition of the third switch 172.

Accordingly, three memory packages selected in the first memory module 130b, three memory packages selected in the second memory module 150b, and three memory packages selected in the third memory module 170b may correspond to one rank. The number of memory packages selected in each of the memory modules 130b, 150b, and 170b for each rank may be the same or different from each other.

Referring to FIGS. 1 and 4, a memory system 100c includes a memory controller 110c and a plurality of memory modules 130c, 150c, and 170c. The memory controller 110c includes an electrical-optical converter 113c having the first light source 210 and the switch signal generator 111.

According to an example embodiment, the first light source 210 and electrical-optical converter 113c may be packaged in one package. That is, the first light source 210 may be manufactured on a die having a vertical cavity surface emitting laser (VCSEL), and the die may be bonded to a die having the electrical-optical converter 113c in a flip-chip method. Accordingly, a cost for manufacturing a light source may be reduced and a size of a system having the light source, e.g., the memory controller 110c, may be decreased.

The electrical-optical converter 113c may perform electrical-optical conversion using an optical signal output from the first light source 210, and may transmit a generated optical signal to a corresponding memory module 130c, 150c, and 170c through a corresponding channel CH1, CH2, and CH3.

The first memory module 130c includes a first package 131c, the first switch 132, and the memory packages 140 to 148, which are mounted on the PCB. The first package 131c includes a first optical-electrical converter O/E and the second light source 220. A die including the first optical-electrical converter O/E and a die including the second light source 220 may be bonded to each other in a flip-chip method.

The first optical-electrical converter O/E of the first package 131c may perform an optical-electrical conversion on an optical signal input through the first channel CH1 using a light source output from the second light source 220. The first switch 132 may transmit an electrical signal output from the first optical-electrical converter O/E to three memory packages 146, 147, and 148 among memory packages 140 to 148.

The second memory module 150c includes a second package 151c, the second switch 152, and the plurality of memory packages 160 to 168, which are mounted on the PCB. The second package 151c includes a second optical-electrical converter O/E and a third light source 230. A die including the second optical-electrical converter O/E and a die including the third light source 230 may be bonded to each other in a flip-chip method.

The second optical-electrical converter O/E of the second package 151c may perform an optical-electrical conversion on an optical signal input through the second channel CH2 using a light source output from the third light source 220. The second switch 152 may transmit an electrical signal output from the second optical-electrical converter O/E to three memory packages 160, 161, and 162 among the plurality of memory packages 160 to 168.

The third memory module 170c includes a third package 171c, the third switch 172, and the memory packages 180 to 188, which are mounted on the PCB. The third package 171c includes a third optical-electrical converter O/E and the fourth light source 240. A die including the third optical-electrical converter O/E and a die including the fourth light source 240 may be bonded to each other in a flip-chip method. The third optical-electrical converter O/E of the third package 171c may perform an optical-electrical conversion on an optical signal input through the third channel CH2 using a light source output from the fourth light source 220.

The third switch 172 may transmit an electrical signal output from the third optical-electrical converter O/E to three memory packages 183, 184, and 185 among the memory packages 180 to 188. Light sources 220, 230, and 240 may be manufactured in VCSEL.

Three memory packages may be selected among nine memory packages 140 to 148 according to a composition of the first switch 132. Three memory packages may be selected among nine memory packages 160 to 168 according to a composition of the second switch 152. Three memory packages may be selected among nine memory packages 180 to 188 according to a composition of the third switch 172.

Accordingly, three memory packages selected in the first memory module 130c, three memory packages selected in the second memory module 150c, and three memory packages selected in the third memory module 170c may correspond to one rank. The number of memory packages in each memory module 130c, 150c, and 170c for each rank may be the same or different from each other.

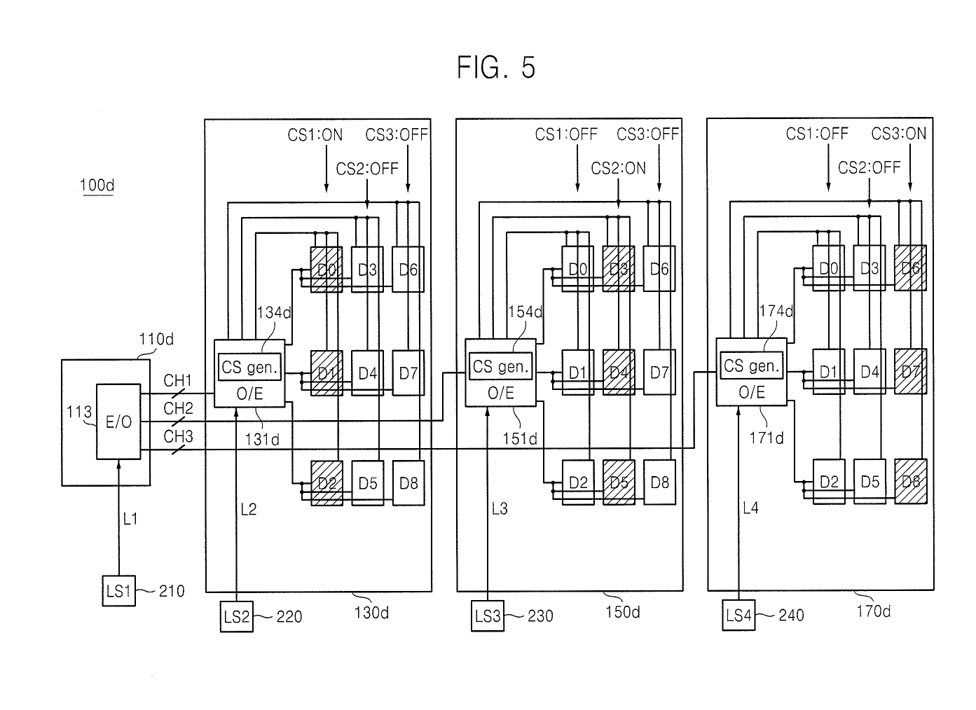

FIGS. 5 to 7 illustrate other embodiments of memory systems using a chip select signal. Referring to FIG. 5, a memory system 100d includes a memory controller 110d and a plurality of memory modules 130d, 150d, and 170d.

The electrical-optical converter 113 of the memory controller 110d may perform an electrical-optical conversion using an optical signal L1 output from the first light source 210 outside the memory controller 110d. The electrical-converter 113 transmits the generated optical signal to a corresponding memory module 130d, 150d, and 170d through a corresponding channel CH1, CH2, and CH3. The first memory module 130d includes a first optical-electrical converter 131d and a plurality of memory packages D0 to D8, which are mounted on the PCB. The second light source 220 may be inside or outside the first memory module 130d.

The plurality of memory packages D0, D3, and D6 of the first memory module 130d share first data signals output from the first optical-electrical converter 131d, a plurality of memory packages D1, D4, and D7 of the first memory module 130d share second data signals output from the first optical-electrical converter 131d, and a plurality of memory packages D2, D5, and D8 of the first memory module 130d share third data signals output from the first optical-electrical converter 131d.

The first optical-electrical converter 131d may include a first chip select signal generator 134d. The first optical-electrical converter 131d or the first chip select signal generator 134d may perform the function of a select circuit.

The first chip select signal generator 134d generates each of the chip select signals CS1, CS2, and CS3 in response to a control signal output from the memory controller 110d. For example, a first chip select signal CS1 controls the ON or OFF states of memory packages D0, D1, and D2 arranged in a column direction. A second chip select signal CS2 controls the ON or OFF states of memory packages D3, D4, and D5 arranged in a column direction. A third chip select signal CS3 controls the ON or OFF states of memory packages D6, D7, and D8 arranged in a column direction.

When the chip select signal CS1 is ON, a memory package performs a normal operation. When the chip select signal CS1 is OFF, the memory package operates in a standby state.

In the first memory module 130d, when the first chip select signal CS1 is ON, the second chip select signal CS2 is OFF, and the third chip select signal CS3 is OFF, memory packages D0, D1, and D2 are selected to perform a normal operation and the remaining memory packages D3 to D8 operate in a standby state. A second memory module 150d includes a second optical-electrical converter 151d and a plurality of memory packages D0 to D8, which are mounted on the PCB. The third light source 230 is located inside or outside the second memory module 150d.

A plurality of memory packages D0, D3, and D6 share first data signals output from the second optical-electrical converter 151d. A plurality of memory packages D1, D4, and D7 share second data signals output from the second optical-electrical converter 151d. A plurality of memory packages D2, D5, and D8 share third data signals output from the second optical-electrical converter 151d.

The second optical-electrical converter 151d may include the second chip select signal generator 154d. The second optical-electrical converter 151d or the second chip select signal generator 154d may perform the function of a select circuit.

The second chip select signal generator 154d generates each chip select signal CS1, CS2, and CS3 in response to a control signal output from the memory controller 110d. For example, the first chip select signal CS1 controls ON or OFF states of memory packages D0, D1, and D2 arranged in a column direction.

The second chip select signal CS2 controls ON or OFF states of memory packages D3, D4, and D5 arranged in a column direction. The third chip select signal CS3 controls ON or OFF states of memory packages D6, D7, and D8 arranged in a column direction.

In the second memory module 150d, when the second chip select signal CS2 is ON, the first chip select signal CS1 is OFF, and the third chip select signal CS3 is OFF, memory packages D3, D4, and D5 are selected and the selected memory packages D3, D4, and D5 perform a normal operation. The remaining rest memory packages D0 to D2 and D6 to D8 operate in a standby state.

The third memory module 170d includes the third optical-electrical converter 171d and the plurality of memory packages D0 to D8, which are mounted on the PCB. The fourth light source 240 may be inside or outside the third memory module 170d.

The plurality of memory packages D0, D3, and D6 arranged in a row direction share first data signals output from the third optical-electrical converter 171d. A plurality of memory packages D1, D4, and D7 arranged in a row direction share second data signals output from the third optical-electrical converter 171d. A plurality of memory packages D2, D5, and D8 arranged in a row direction share third data signals output from the third optical-electrical converter 171d.

The third optical-electrical converter 171d may include a third chip select signal generator 174d. The third optical-electrical converter 171d or the third chip select signal generator 174d may perform a function of a select circuit.

The third chip select signal generator 174d generates each of the chip select signals CS1, CS2, and CS3 in response to a control signal output from the memory controller 110d. For example, the first chip select signal CS1 controls ON or OFF states of the memory packages D0, D1, and D2. The second chip select signal CS2 controls ON or OFF states of the memory packages D3, D4, and D5. The third chip select signal CS3 controls ON or OFF states of the memory packages D6, D7, and D8.

In the third memory module 170d, when the third chip select signal CS3 is ON, the first chip select signal CS1 is OFF, and the second chip select signal CS2 is OFF, the memory packages D6, D7, and D8 are selected and the selected memory packages D6, D7, and D8 perform a normal operation. The remaining memory packages D0 to D5 operate in a standby state.

Three memory packages D0, D1, and D2 normally operating in the first memory module 130d, three memory packages D3, D4, and D5 normally operating in the second memory module 150c, and three memory packages D6, D7, and D8 normally operating in the third memory module 170c may correspond to one rank.

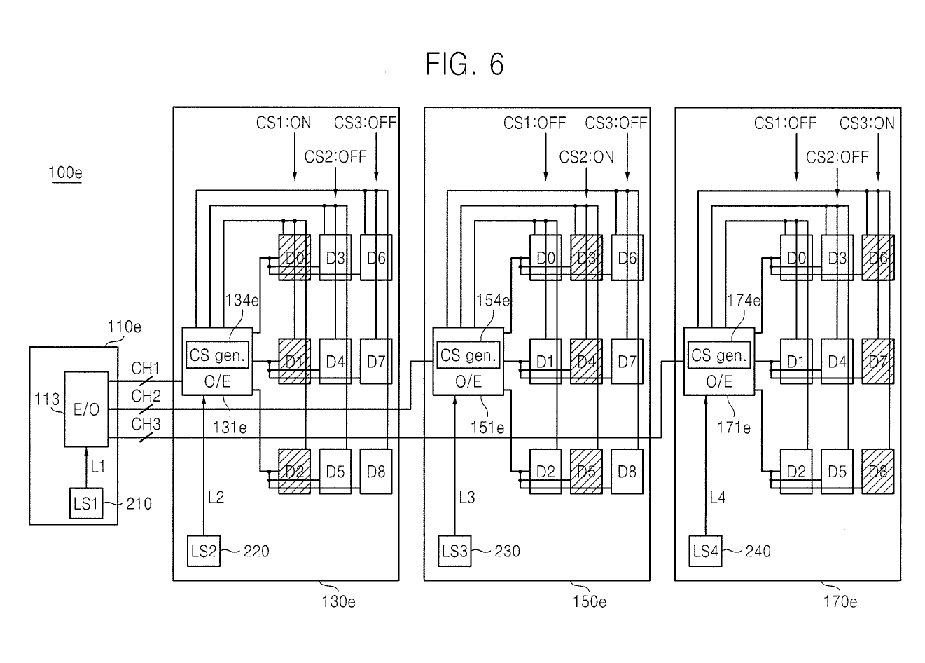

Referring to FIGS. 1 and 6, a memory system 100e includes a memory controller 110e and a plurality of memory modules 130e, 150e, and 170e. The memory controller 110e includes the electrical-optical converter 113 and the first light source 210. The electrical-optical converter 113 may perform an electrical-optical conversion using an optical signal L1 output from the first light source L1. The electrical-optical converter 113 may transmit a generated optical signal to a corresponding memory module 130e, 150e, and 170e through a corresponding channel CH1, CH2, and CH3.

The first memory module 130e includes a first optical-electrical converter 131e, the second light source 220, and the plurality of memory packages D0 to D8, which are mounted on the PCB. The second light source 220 is mounted on the first memory module 130e. Otherwise, the structure and operation of the first memory module 130d of FIG. 5 may be substantially the same as the first memory module 130e of FIG. 6.

The first optical-electrical converter 131e may include a first chip select signal generator 134e. The first chip select signal generator 134e generates each of the chip select signals CS1, CS2, and CS3 in response to a control signal output from the memory controller 110e.

The second memory module 150e includes a second optical-electrical converter 151e, the third light source 230, and the plurality of memory packages D0 to D8, which are mounted on the PCB. The third light source 230 is mounted on the second memory module 150e. Otherwise, the structure and operation of the second memory module 150d of FIG. 5 are substantially the same as the second memory module 150e of FIG. 6.

The second optical-electrical converter 151e may include a second chip select signal generator 154e. The second chip select signal generator 154e generates each of the chip select signals CS1, CS2, and CS3 in response to a control signal output from the memory controller 110e.

The third memory module 170e includes a third optical-electrical converter 171e, the fourth light source 240, and the plurality of memory packages D0 to D8, which are mounted on the PCB. The fourth light source 240 is mounted on the third memory module 170e. The structure and operation of the third memory module 170d are substantially the same as the third memory module 170e of FIG. 6.

The third optical-electrical converter 171e may include a third chip select signal generator 174e. The third chip select signal generator 174e generates each of the chip select signals CS1, CS2, and CS3 in response to a control signal output from the memory controller 110e.

Three memory packages D0, D1, and D2 normally operating in the first memory module 130e, three memory packages D3, D4, and D5 normally operating in the second memory module 150e, and three memory packages D6, D7, and D8 normally operating in the third memory module 170e may correspond to a same rank.

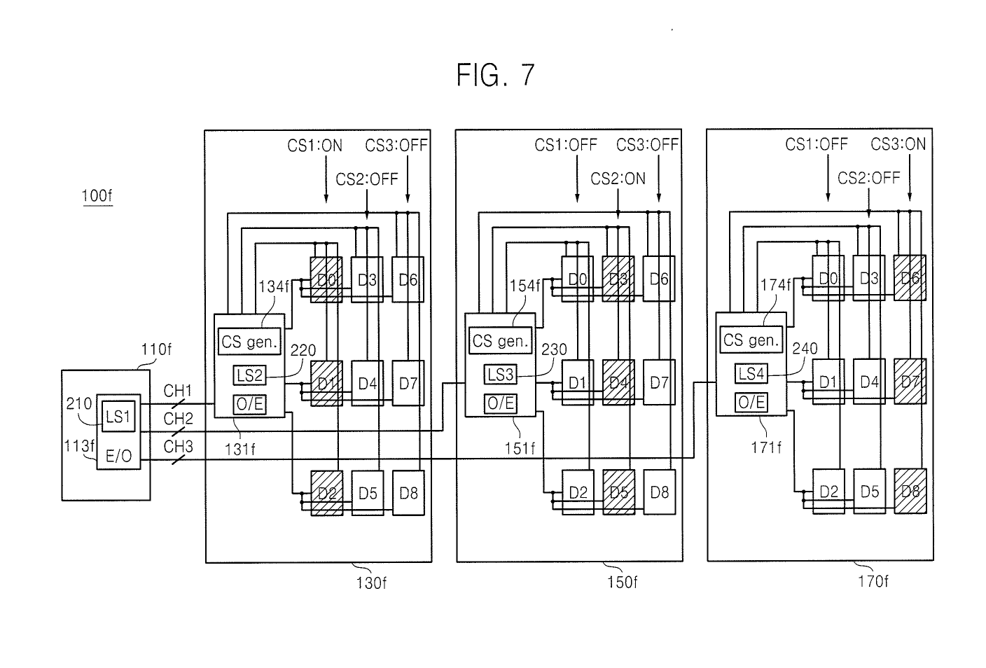

Referring to FIG. 7, a memory system 100f includes a memory controller 110f and a plurality of memory modules 130f, 150f, and 170f. The memory controller 110f includes an electrical-optical converter 113f having the first light source 210.

The electrical-optical converter 113f having the first light source 210 may be packaged in one package. For example, the first light source 210 may be manufactured in a die having VCSEL, and the die may be bonded to a die having the electrical-optical converter 113f in a flip-chip method.

The electrical-optical converter 113f may perform an electrical-optical conversion using an optical signal output from the first light source 210. The electrical-optical converter 113f may transmit a generated optical signal to a corresponding memory module 130f, 150f, and/or 170f through a corresponding channel CH1, CH2, and/or CH3.

The first memory module 130f includes a first package 131f and a plurality of memory packages D0 to D8, which are mounted on the PCB. The first package 131f may include the first optical-electrical converter O/E, the second light source 220, and the first chip select signal generator 134f.

The first optical-electrical converter O/E performs an optical-electrical conversion using an optical signal output from the second light source 220, and supplies a generated electrical signal to the plurality of memory packages D0 to D8. The first chip select signal generator 134f generates each of the chip select signals CS1, CS2, and CS3 in response to a control signal output from the memory controller 110f.

Except for the first package 131f, the structure and operation of the first memory module 130d of FIG. 5 may be substantially the same as the first memory module 130f of FIG. 7. The second memory module 150f includes a second package 151f and the plurality of memory packages D0 to D8, which are mounted on the PCB.

The second package 151f may include a second optical-electrical converter O/E, the third light source 230, and the second chip select signal generator 154f. The second optical-electrical converter O/E performs an optical-electrical conversion using an optical signal output from the third light source 230. The second optical-electrical converter O/E may supply a generated electrical signal to the plurality of memory packages D0 to D8.

The second chip select signal generator 154f generates each of the chip select signals CS1, CS2, and CS3 in response to a control signal output from the memory controller 110f. Except for the second package 151f, the structure and operation of the second memory module 150d of FIG. 5 may be substantially the same as the second memory module 150f of FIG. 7.

The third memory module 170f includes a third package 171f and the plurality of memory packages D0 to D8, which are mounted on the PCB. The third package 171f may include a third optical-electrical converter O/E, the fourth light source 240, and the third chip select signal generator 174f.

The third optical-electrical converter O/E performs an optical-electrical conversion using an optical signal output from the fourth light source 240. The third optical-electrical converter O/E supplies a generated electrical signal to the plurality of memory packages D0 to D8. The third chip select signal generator 174f generates each of the chip select signals CS1, CS2, and CS3 in response to a control signal output from the memory controller 110f.

Except for the third package 171f, the structure and operation of the third memory module 170d of FIG. 5 may be substantially the same as the third memory module 170f of FIG. 7.

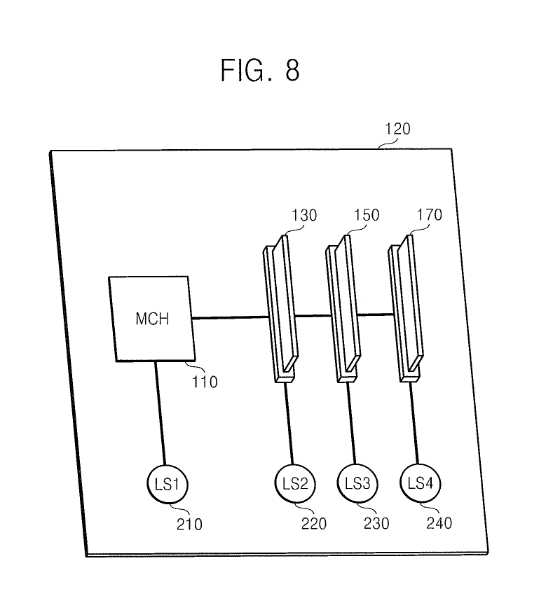

FIG. 8 illustrates an example embodiment where each of a plurality of light sources 210, 220, 230 and 240 is mounted on the mother board 120. The plurality of light sources 210, 220, 230, and 240 may be mounted on respective ones of the memory modules 130, 150, and 170, as illustrated in FIG. 3 or 6. In an alternative embodiment, the light sources 210, 220, 230, and 240 may be included in a corresponding package, as illustrated in FIG. 4 or 7.

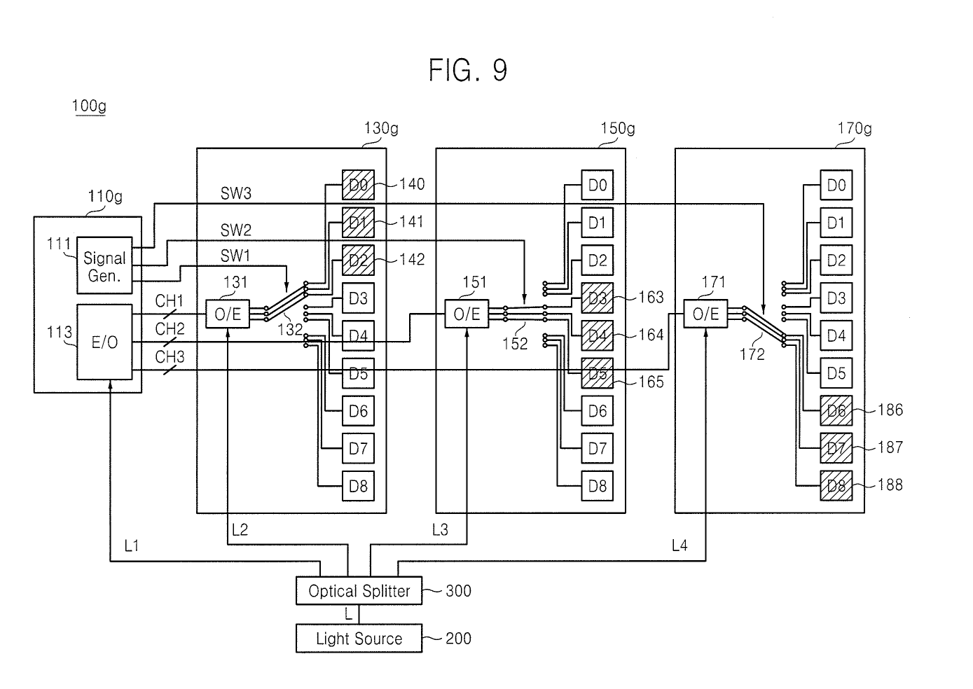

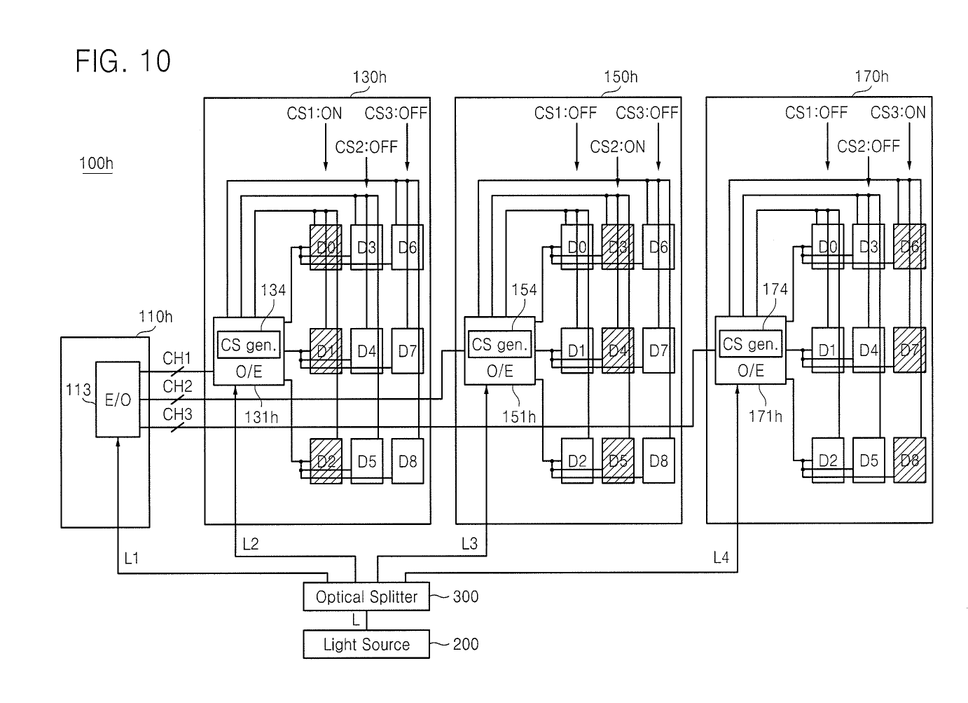

FIGS. 9 to 10 illustrate other embodiments of memory systems using an optical splitter. Referring to FIG. 9, a memory system 100g includes a memory controller 110g, a plurality of memory modules 130g, 150g, and 170g, a light source 200, and an optical splitter 300. The structure and operation of the memory controller 110a of FIG. 2 may be substantially the same as the memory controller 110g of FIG. 9. The structure and operation of each of the memory module 130a, 150a, and 170a may be substantially the same as respective ones of the memory module 130g, 150g, and 170g of FIG. 9.

The light sources 210, 220, 230, and 240 of FIG. 2 may independently operate in FIG. 2. In one embodiment, an optical signal output from one light source 200 of FIG. 8 may be divided into a plurality of optical signals L1, L2, L3, and L4 by the optical splitter 300. Also, each of the optical signals L1, L2, L3, and L4 may be supplied to respective components 110g, 130g, 150g, and 170g.

Referring to FIG. 10, a memory system 100h includes a memory controller 110h, a plurality of memory modules 130h, 150h, and 170h, the light source 200, and the optical splitter 300.

The structure and operation of the memory controller 110d of FIG. 5 may be substantially the same as the memory controller 110h of FIG. 10. The structure and operation of memory modules 130d, 150d, and 170d of FIG. 5 may be substantially the same as memory modules 130h, 150h, and 170h of FIG. 10, respectively. The structure and operation of components 131d, 151d, and 171d of FIG. 5 may be substantially the same as components 131h, 151h, and 171h of FIG. 10, respectively.

The structure and operation of components 134d, 154d, and 174d of FIG. 5 may be substantially the same as components 134, 154, and 174 of FIG. 10, respectively. The light sources 210, 220, 230, and 240 of FIG. 5 operate independently from each other. In an alternative embodiment, an optical signal output from one light source 200 in FIG. 10 is partitioned into a plurality of optical signals L1, L2, L3, and L4 by the optical splitter 300. The optical signals L1, L2, L3, and L4 are then supplied to respective ones of the components 110h, 130h, 150h, and 170h.

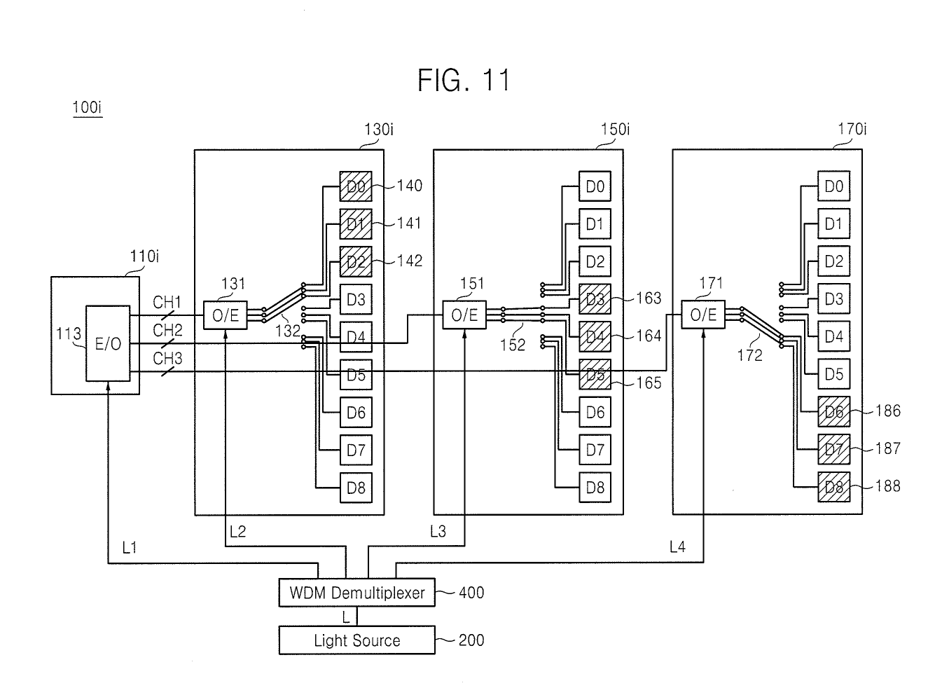

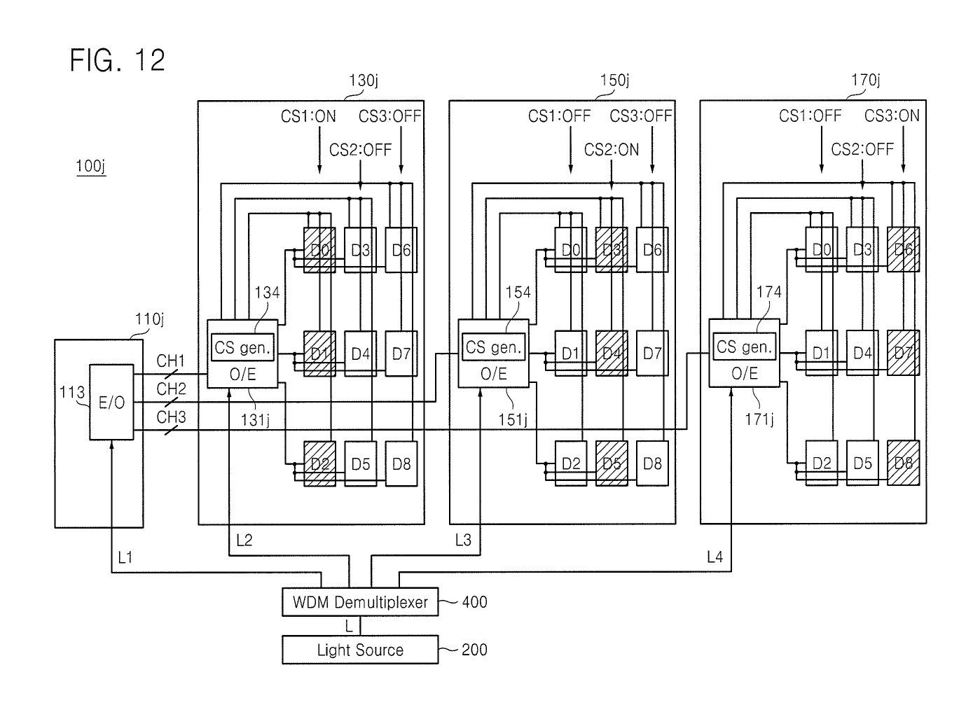

FIGS. 11 to 12 illustrate other embodiments of memory systems that use a wavelength division multiplexing demultiplexer. Referring to FIG. 11, a memory system 100i includes a memory controller 110i, a plurality of memory modules 130i, 150i, and 170i, the light source 200, and a wavelength division multiplexing (WDM) demultiplexer 400.

The WDM demultiplexer 400 receives an optical signal L generated in the light source 200, partitions the received optical signal L according to a wavelength, generates a plurality of optical signals L1, L2, L3, and L4 each having a different wavelength, and supplies each of the plurality of generated optical signals L1, L2, L3, and L4 to each component 110i, 130i, 150i, and 170i.

Referring to FIG. 12, a memory system 100j includes a memory controller 110j, a plurality of memory modules 130j, 150j, and 170j, light source 200, and wavelength division multiplexing (WDM) demultiplexer 400. The structure and operation of the memory controller 110h of FIG. 10 may be substantially the same as the memory controller 110j of FIG. 12.

The structure and operation of memory module 130h, 150h, and 170h of FIG. 10 may be substantially the same as memory module 130j, 150j, and 170j of FIG. 12, respectively. In addition, the structure and operation of components 131h, 151h, and 171h of FIG. 10 may be substantially the same as components 131j, 151j, and 171j of FIG. 12.

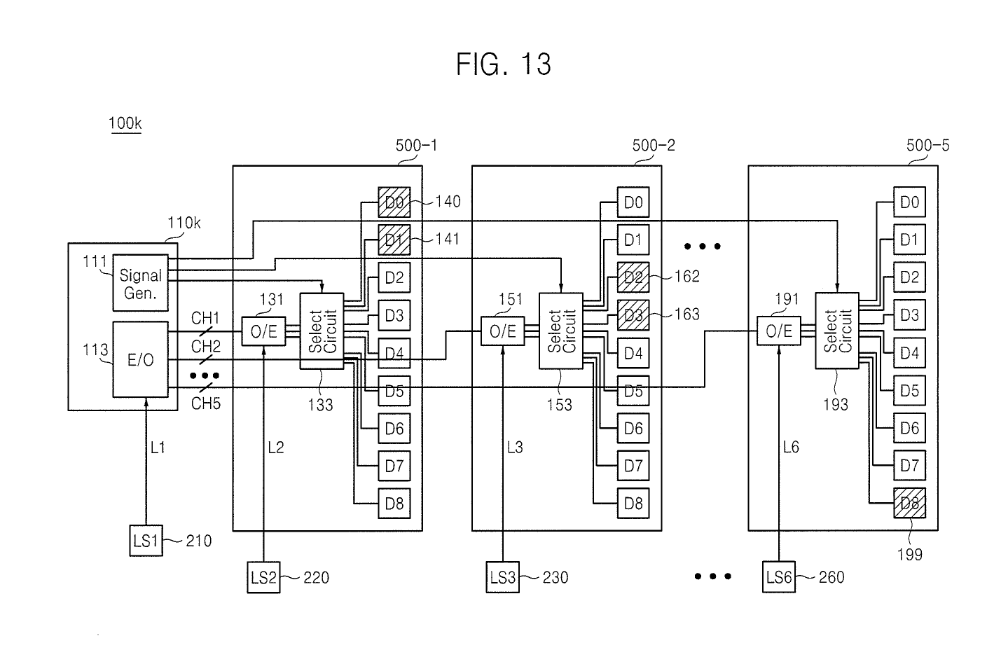

FIG. 13 illustrates another embodiment of a memory system 100k including five memory modules. Referring to FIG. 13, memory system 100k includes a memory controller 110k, a plurality of memory modules 500-1, 500-2, . . . , 500-5, and a plurality of light sources 210, 220, 230, . . . , 260. The structure and operation of the memory controller 110 of FIG. 1 may be substantially the same as the memory controller 110k of FIG. 13.

The switch signal generator 111 generates select signals for controlling respective ones of select circuits 133, 153, . . . , 193 mounted on each memory module 500-1, 500-2, . . . , 500-5. The electrical-optical converter 113 performs an electrical-to-optical conversion using an optical signal L1 output from the first light source 210. The electrical-optical converter 113 transmits a generated optical signal to each memory module 500-1, 500-2, . . . , 500-5 through a respective one of channels CH1 to CH5.

The optical-electrical converters 131, 151, . . . , 191 convert the optical signals received through channels CH1 to CH5 to electrical signals using respective ones of optical signals L2, L3, . . . , L6 output from light sources 220, 230, . . . , 260. Each select circuit 133, 153, . . . , 193 transmits an electrical signal output from a corresponding optical-electrical converter 131. 151, . . . , 191 to at least a corresponding memory package in response to a select signal.

In one embodiment, every two memory packages from a first memory module to a fourth memory module 500-1 to 500-4 may be selected. In other embodiments, and one memory package 199 may be selected in a fifth memory module 500-5.

In accordance with one or more of the aforementioned embodiments, a memory system includes an optical channel to reduce manufacturing costs of a light source, and also the size of the memory system. Also, in accordance with one or more embodiments, a memory system is provided to reduce or eliminate switch losses of the light source. The light source may be mounted on a memory module or may be integrated on the light source of an optical converter. Also, in accordance with at least one embodiment, a memory module which includes a select circuit, and a memory system which includes the memory module, may transmit data with reduced optical power.

Example embodiments have been disclosed herein, and although specific terms are employed, they are used and are to be interpreted in a generic and descriptive sense only and not for purpose of limitation. In some instances, as would be apparent to one of skill in the art as of the filing of the present application, features, characteristics, and/or elements described in connection with a particular embodiment may be used singly or in combination with features, characteristics, and/or elements described in connection with other embodiments unless otherwise indicated. Accordingly, it will be understood by those of skill in the art that various changes in form and details may be made without departing from the spirit and scope of the present invention as set forth in the following claims.

What is claimed is:

1. A memory module, comprising:
a printed circuit board (PCB);
a plurality of memory packages on the PCB;
an optical-electrical converter on the PCB; and
a select circuit on the PCB to select at least one of the memory packages, wherein the at least one memory package is to process electrical signals output from the optical-electrical converter.

2. The memory module as claimed in claim 1, wherein the select circuit includes a switch circuit to transmit the electrical signals to the at least one memory package in response to a switch signal from a memory controller.

3. The memory module as claimed in claim 1, wherein the select circuit is to enable the at least one memory package only in response to a control signal from a memory controller.

4. The memory module as claimed in claim 1, further comprising:
a light source on the PCB,
wherein the optical-electrical converter is to convert input optical signals to the electrical signals in response to an optical signal from the light source.

5. The memory module as claimed in claim 4, wherein the optical-electrical converter and the light source are included in one package.

6. The memory module as claimed in claim 5, wherein:
the light source is included in a first chip,
the optical-electrical converter is included in a second chip, and
the first chip is bonded to the second chip based on a flip-chip configuration.

7. The memory module as claimed in claim 1, wherein the optical-electrical converter deserializes a serialized input optical signal to generate the electrical signals.

8. A memory system, comprising:
a plurality of memory modules; and
a memory controller to control the memory modules,
wherein each of the memory modules includes:
a printed circuit board (PCB);
a plurality of memory packages on the PCB;
an optical-electrical converter on the PCB; and
a select circuit on the PCB to select at least one of the memory packages, wherein the at least one memory package is to process electrical signals output from the optical-electrical converter.

9. The memory system as claimed in claim 8, further comprising:
a plurality of light sources allocated to respective ones of the memory modules, wherein the optical-electrical converter of each of the memory modules is to convert input optical signals to the electrical signals in response to an optical signal output from a respective one of the light sources.

10. The memory system as claimed in claim 9, wherein the light sources are mounted on respective ones of the memory modules.

11. The memory system as claimed in claim 9, wherein the optical-electrical converter of respective ones of the memory modules and a respective one of the light sources are included in one package.

12. The memory system as claimed in claim 8, further comprising:
a plurality of optical channels connected between the memory controller and the optical-electrical converter of respective ones of the memory modules.

13. The memory system as claimed in claim 8, wherein the select circuit includes a switch circuit to transmit the electrical signals to at least one of the memory packages in response to a switch signal from the memory controller.

14. The memory system as claimed in claim 8, wherein the select circuit is to enable the at least one memory package only in response to a control signal from the memory controller.

15. The memory system as claimed in claim 8, wherein the memory controller includes:
a light source; and
an electrical-optical converter to convert electrical signals to be transmitted to the memory modules into optical signals in response to an optical signal output from the light source, wherein the light source and electrical-optical converter are included in one package.

16. A memory system, comprising:
a controller;
a first memory module including a first number of memory packages and a second number of memory packages; and
a second memory module including a third number of memory packages and a fourth number of memory packages, wherein the first and third numbers of memory packages are selected to correspond to a same rank based on control signals from the controller and wherein the control signals are transmitted from the controller to the first and second memory modules through respective ones of a plurality of optical channels.

17. The memory system as claimed in claim 16, further comprising:
a first selector to select the first number of memory packages, and
a second selector to select the third number of memory packages.

18. The memory system as claimed in claim 17, further comprising:
a first optical-to-electrical (O/E) converter between the controller and the first selector; and
a second O/E converter between the controller and the second selector,
wherein the first O/E converter is to convert the control signal through a first one of the optical channels based on a first light signal and wherein the second O/E converter is to convert the control signal through a second one of the optical channels based on a second light signal.

19. The memory system as claimed in claim 18, wherein the first and second light signals have different optical wavelengths.

20. The memory system as claimed in claim 16, wherein:
the second number of memory packages are in a column different from the second number of memory packages, and
the fourth number of memory packages are in a column different from the third number of memory packages.
